(19) United States
(12) Patent Application Publication
(10) Pub. No.: US 2010/0326707 A1
(43) Pub. Date: Dec. 30, 2010

(54) METHAL-BASED PACKAGE SUBSTRATE, THREE-DIMENSIONAL MULTI-LAYERED PACKAGE MODULE USING THE SAME, AND MANUFACTURING METHOD THEREOF

(75) Inventors: Young-Se Kwon, Daejeon-City (KR); Kyoung-Min Kim, Seoul (KR); Je-In Yu, Ansan-City (KR)

Correspondence Address: GIFFORD, KRASS, SPRINKLE,ANDERSON & CITKOWSKI, P.C, PO BOX 7021, TROY, MI, 48007-7021, US

(73) Assignees: Wavenics Inc., Daejeon-city (KR); Korea Advanced Institute of Science and Technology, Daejeon-City (KR)

(21) Appl. No.: 12/667,263

(22) PCT Filed: Sep. 18, 2007
(86) PCT No.: PCT/KR07/04487

§ 371 Date: Dec. 30, 2009

(30) Foreign Application Priority Data
Jul. 31, 2007 (KR) 10-2007-0076676

(51) Int. Cl. H05K 1/09; H05K 1/11; H05K 1/18; H01R 43/00

(52) U.S. Cl. 174/257; 174/264; 174/260; 29/825

(57) ABSTRACT

A package substrate, a manufacturing method thereof, a base package module, and a multi-layered package module having package substrates laminated on upper and lower portions of a base package module are provided. The base package module includes a base metal substrate, a first metal oxide layer that is formed on the base metal substrate to have a cavity therein, a device that is mounted in the cavity on the base metal substrate and insulated by the first metal oxide layer formed on a sidewall in the cavity, and a conductor that is connected to the device and a wiring pad formed on the first metal oxide layer on the base metal substrate. The package substrate includes a wiring pad, a conductor line, a second metal oxide layer having an opening that exposes a device, and a via that is connected to the wiring pad through a connection pad in the second metal oxide layer.

### TECHNICAL FIELD

The present invention relates to a multi-layered package module and a manufacturing method thereof and, more particularly, to a multi-layered package module using a metal substrate and a manufacturing method thereof.

### BACKGROUND ART

As the degree of integration of semiconductor devices is increased and various functions are provided to the semiconductor devices, the packaging process tends to be changed from a process suitable for a small number of pins of a package to a process suitable for a large number of pins of the package. In addition, a conventional structure for mounting the package on a printed circuit board (PCB) has been replaced with a surface mounting structure. Many types of packages with the surface mounting structure have been proposed, for example a small outline package (SOP), a plastic leaded chip carrier (PLCC), a quad flat package (QFP), a ball grid array (BGA), and a chip scale package (CSP).

A printed circuit board (PCB) or a low temperature co-fired ceramic (LTCC) board associated with the semiconductor device needs to have thermal, electrical, and mechanical stability. Conventionally, the PCB has been manufactured by using expensive ceramic substrates or resin substrates made of a polyimide-based resin, a fluoride-based resin, or a silicon-based resin. The LTCC board has been manufactured by using a ceramic substrate. Since the ceramic substrate or the resin substrate used for the LTCC board or the PCB is an insulator, an insulating material does not need to be applied after a through-hole process.

However, since the resin substrate has poor water-resistance and heat-resistance, the resin substrate has a problem in that the resin substrate is not usable for a chip-carrier substrate. Although the ceramic substrate has better heat resistance than that of the resin substrate, the ceramic substrate has problems in that the ceramic substrate is also expensive and hard to process, and has a high production cost.

On the other hand, recently, as products tend to be manufactured in a small-sized thin type, a board having a thin thickness and a flat surface has been demanded. As an approach for implementing such a thin and flat product, cavities are formed on pre-determined portions of the substrate, and the chips or parts are mounted in the cavities.

### DISCLOSURE OF INVENTION

### Technical Problem

In a conventional method of forming the cavities, the cavities have been formed by drilling a resin substrate. When using the method, cavity processing time and cost are increased. In addition, since a deviation of the cavities is large, parts mounted therein may be easily slanted, so that it is difficult to maintain a predetermine flatness of the substrate. Moreover, since the resin used for the substrate has poor thermal and mechanical characteristics, if the parts are mounted in the cavities formed in the resin substrate, serious stress and deformation may occur in the resin substrate.

The above information disclosed in this Background section is only for enhancement of understanding of the background of the invention and therefore it may contain information that does not form the prior art that is already known in this country to a person of ordinary skill in the art.

The present invention has been made in an effort to provide a package substrate and a multi-layered package module using the package substrate having advantages of overcoming problems of a printed circuit board (PCB) constructed with a ceramic substrate or a resin substrate. The present invention has also been made in an effort to provide a method of manufacturing the package substrate and a method of manufacturing the multi-layered package module.

### Technical Solution

An exemplary embodiment of the present invention provides package substrate including a plate-shaped metal oxide layer, and at least one metal via that is formed to penetrate at least one portion of the metal oxide layer and to have a thickness equal to that of the metal oxide layer, wherein the metal oxide layer is formed by oxidizing the entire surface of a metal substrate without a mask, and the metal via corresponds to a portion that is not oxidized during the oxidation of the metal substrate for forming the metal oxide layer.

In the above embodiment, the metal may be aluminum and the metal oxide layer may be alumina.

The package substrate may further include a metal plate that is disposed in the metal oxide layer.

The package substrate may further include one or more through-holes that penetrate predetermined portions of the metal oxide layer. In addition, the package substrate may further include vias that are formed along inner walls of the through-holes to extend onto a portion of the metal oxide layer.

The package substrate may further include a device mounting portion that is constructed by forming a metal layer on a lower surface of the metal oxide layer and forming a cavity on an upper surface of the metal layer. In addition, a device mounted on the device mounting portion and the package substrate may be connected to each other through a conductor line.

Another embodiment of the present invention provides a multi-layered package module having layered package substrates, wherein the package substrates are laminated by contacting connection pads that are disposed on upper and lower portions of vias.

Yet another embodiment of the present invention provides a multi-layered package module having a base package module and package substrates laminated on upper and lower portions of the base package module, wherein each of the package substrate includes a wiring pad, a conductor line, a second metal oxide layer having an opening that exposes a device, and a via that is connected to the wiring pad through a connection pad in the second metal oxide layer.

In the above embodiment, upper portions of the wiring pad, the conductor line, and the device in the opening of the package substrate may be filled with an insulating layer.

Still another embodiment of the present invention provides a base package module, including a base metal substrate, a first metal oxide layer that is formed on the base metal substrate to have a cavity therein, a device that is mounted in the cavity on the base metal substrate and insulated by the first metal oxide layer formed on a sidewall in the cavity, and a conductor that is connected to the device and a wiring pad formed on the first metal oxide layer on the base metal substrate.

In the above embodiment, the base package module may further include a via that connects upper and lower portions.

The first metal oxide layer may be formed on a bottom portion of the cavity where the device is mounted. In addition, an electrode may be formed on the bottom portion of the cavity on the first metal oxide layer.

The base package module and the package substrates may be adhered to each other with an adhesive layer.

A penetrating through-hole or a non-penetrating hole may be formed.

A passive device may be formed on the metal oxide layer of the package substrate.

Surface mounting types of parts may be mounted on the metal oxide layer of the uppermost package substrate or base package module.

An active device or a passive device may be disposed in an inner portion of the package substrate

Further still another embodiment of the present invention provides a method of manufacturing a multi-layered package module, wherein the forming of the cavity and the metal oxide layer includes forming the metal oxide layer by performing selective anodic oxidation on the base metal substrate, and forming the cavity by selectively etching the metal oxide layer to expose the base metal substrate.

In the above embodiment, in the selectively etching of the metal oxide layer, a portion of the metal oxide layer may be left on the base metal substrate.

Further still another embodiment of the present invention provides a method of manufacturing a package substrate, including forming recesses by removing predetermined portions of upper and lower surfaces of a metal substrate, leaving a predetermined thickness of a metal constituting the metal substrate in portions where the recesses are not formed by oxidizing the entire surface of the metal substrate without a mask until portions of the metal substrate corresponding to the recesses are completely oxidized, and forming vias by polishing both surfaces of the resulting product until metal surfaces remaining in the portions where the recesses are not formed are exposed.

In the above embodiment, the recesses may be formed by etching and removing the predetermined portions.

The recesses may be formed by pressing with a pressing apparatus.

The forming of the recess may include forming the recesses having non-uniform depths on the upper surface of the metal substrate, and forming the recesses having non-uniform depths on the lower surface of the metal substrate.

The method may further include forming the recesses of the metal substrate in an asymmetrical structure, leaving a predetermined thickness of a metal constituting the metal substrate in portions where the recesses are not formed by oxidizing the metal substrate to form the metal oxide layer, and forming a device mounting portion having a metal layer on a lower surface thereof by polishing a lower surface of the resulting product until metal surfaces remaining in the portions where the recesses are not formed are exposed and by etching an upper surface of the metal oxide layer.

### Advantageous Effects

According to the present invention, the multi-layered package module is constructed and manufactured by using a metal substrate. Therefore, since the substrate used for the multi-layered package module according to the present invention is inexpensive and easy to process in comparison to the PCB and the LTCC board, it is possible to manufacture the multi-layered package module at a low cost.

According to the present invention, since the multi-layered package module is constructed by using a metal substrate, it is possible to obtain the multi-layered package module having good thermal reliability and good heat releasing efficiency in comparison to the PBB and the LTCC board.

In addition, in the multi-layered package module according to the present invention, the cavity is formed by etching the metal oxide layer formed by using the metal substrate, the cavity can be easily processed, and a deviation of the cavity can be reduced.

In addition, according to the present invention, since the multi-layered package module is formed by using the metal substrate, it is possible to obtain good thermal and mechanical characteristics.

### BRIEF DESCRIPTION OF THE DRAWINGS

FIG. 1 is a cross-sectional view illustrating a multi-layered package module according to an embodiment of the present invention.

FIGS. 2 to 6 are cross-sectional views for explaining a structure of a package substrate and a manufacturing method thereof according to an embodiment of the present invention.

FIGS. 7 to 9 are cross-sectional views for explaining a structure of a package substrate and a manufacturing method thereof according to another embodiment of the present invention.

FIGS. 10 to 12 are cross-sectional views for explaining a structure of a package substrate and a manufacturing method thereof according to still another embodiment of the present invention.

FIGS. 13 and 14 are cross-sectional views for explaining a structure of a package substrate and a manufacturing method thereof according to further still another embodiment of the present invention.

FIGS. 15 to 21 are cross-sectional views for explaining a structure of a package substrate and a manufacturing method thereof according to further still another embodiment of the present invention.

FIGS. 22 to 28 are cross-sectional views for explaining a structure of a package substrate and a manufacturing method thereof according to further still another embodiment of the present invention.

FIGS. 29 to 33 are cross-sectional views for explaining a base package module and a manufacturing method thereof according to an embodiment of the present invention.

FIGS. 34 to 39 are cross-sectional views for explaining a base package module and a manufacturing method thereof according to another embodiment of the present invention.

FIGS. 40 to 42 are cross-sectional views for explaining a connection pad structure of a package substrate and a formation method thereof according to an embodiment of the present invention.

FIGS. 43 and 44 are cross-sectional views for explaining a connection pad structure of a package substrate and a formation method thereof according to another embodiment of the present invention.

FIGS. 45 to 47 are cross-sectional views for explaining a multi-layer laminating method for package substrates and a multi-layer lamination structure according to an embodiment of the present invention.

FIGS. 48 and 49 are cross-sectional views for explaining a multi-layer laminating method for package substrates and a multi-layer lamination structure according to another embodiment of the present invention.

FIG. 50 is a cross-sectional view for explaining a multi-layer laminating method for package substrates and a multi-layer lamination structure according to still another embodiment of the present invention.

### BEST MODE FOR CARRYING OUT THE INVENTION

Hereinafter, exemplary embodiments of the present invention are described in detail with reference to the accompanying drawings.

A multi-layered package module according to the present invention is manufactured by using a metal substrate in order to overcome drawbacks of a printed circuit board (PCB) or a low temperature co-fired ceramic (LTCC) board manufactured by using a resin substrate or a ceramic substrate. Therefore, since the metal substrate used for the multi-layered package module according to the present invent is inexpensive and easy to process in comparison to the PCB and the LTCC board, it is possible to manufacture the multi-layered package module at a low cost.

Since the metal substrate used to manufacture the multi-layered package module according to the present invention has excellent heat releasing efficiency in comparison to the PCB and the LTCC board, circuit devices that are vulnerable to heat can be mounted thereon. In addition, since the LTCC board thermally contracts during a sintering process, a variation in size of a pattern thereon is increased. However, in the case of using the metal substrate according to the present invention, the multi-layered package module is manufactured at a low temperature, so that thermal contraction thereof does not occur.

Hereinafter, exemplary multi-layered package modules are schematically described, and thus the present invention is not limited thereto.

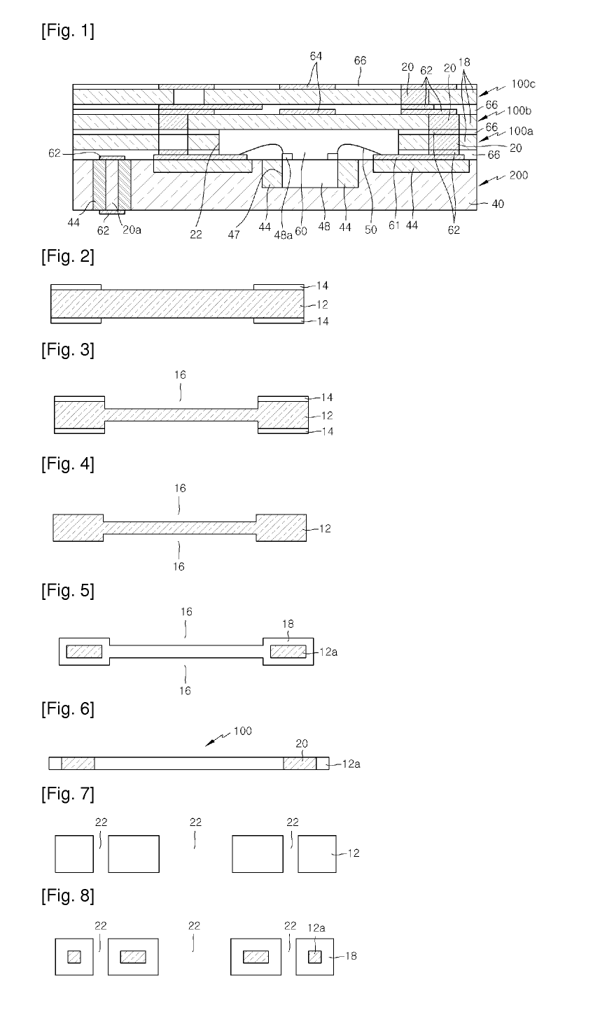

FIG. 1 is a cross-sectional view illustrating a multi-layered package module according to an embodiment of the present invention.

Referring to FIG. 1, the multi-layered package module includes a base package module 200 and a plurality of package substrates 100a, 100b, and 100c that are sequentially laminated on the base package module 200. In the base package module 200, a metal oxide layer 44 is formed in a base metal substrate 40, and a cavity 47 is formed at a predetermined portion of the metal oxide layer 44, so that metal oxide layer 44 can be disposed on a side surface of the cavity 47. A device (chip) 48, for example an active device or a passive device, is attached (mounted) on the base metal substrate 40 in the cavity 47 and insulated by the metal oxide layer 44. The base metal substrate 40 may be constructed with an aluminum substrate, and the metal oxide layer 44 may be constructed with an aluminum oxide (alumina) layer. Wiring pads 61 are disposed at both sides of the device 48, and electrodes 48a of the device 48 are connected to the wiring pads 61 through wire lines 50. Another metal oxide layer 44 may be formed under the wiring pads 61. Particularly, in the case of connecting the base metal substrate to ground, the metal oxide layer 44 may not be formed.

The first package substrate 100a is laminated on the base package module 200. The first package substrate 100a includes a second metal oxide layer 18 having an opening to expose the wiring pads 61, the wire lines 50, and the device 48, and a via 20 that is connected to a predetermined portion of the metal oxide layer 18 through the wiring pad 61 to a connection pad 62. The upper portion of the wiring pads 61, the wire lines 50, and the device 48 in the through-hole 22 is filled with an insulating layer 60, for example, a polyimide layer. The insulating layer 60 may not be formed if it is not needed. The base package module 200 and the first package substrate 100a are adhered to each other by using an adhesive layer 66. The first package substrate 100a functions as a connecting member for connecting to the to-be-laminated second package substrate 100b. In addition, passive devices (not shown) may be formed on the first package substrate 100a.

The second package substrate 100b is laminated on the first package substrate 100a and the through-hole 22. The second package substrate 100b includes a metal oxide layer 18 and a via 20 that is connected to the connection pads 62 formed on the upper and lower surfaces of the metal oxide layer 18. A passive device 64 is mounted on the central portion of the second package substrate 100b. The first package substrate 100a and the second package substrate 100b are adhered to each other by using an adhesive layer 66.

Similar to the second package substrate 100b, the third package substrate 100c is laminated on the second package substrate 100b. The third package substrate 100c includes a via 20 that is connected to the connection pad 62. A passive device 64 is mounted on the central portion of the third package substrate 100c. Surface mounting parts may be mounted on the third package substrate 100c. The second package substrate 100b and the third package substrate 100c are adhered to each other by using an adhesive layer 66.

In the embodiment shown in FIG. 1, although the three package substrates 100a, 100b, and 100c are laminated, only two package substrates or a larger number of the package substrate may be laminated, as needed. Hereinafter, all the package substrates are collectively denoted by reference numeral 100. In addition, on the lower surface of the base package module 200, another base package module or another package substrate may be laminated, or a via 20a may be formed to be connected to an external connecting land or the like. Hereinafter, various types of the package substrates 100, various types of the base package modules 200, and various types of the manufacturing methods are described, and they are implemented based on the construction shown in FIG. 1. In addition, a laminating structure of the package substrates 100 and a laminating method thereof are described in detail.

A package substrate and manufacturing method thereof will be described.

FIGS. 2 to 6 are cross-sectional views for explaining a structure of a package substrate and a manufacturing method thereof according to an embodiment of the present invention.

Referring to FIGS. 2 to 6, a metal substrate 12, for example an aluminum substrate, is prepared. Mask layers 14 are formed on the upper and lower surfaces of the metal substrate 12. Some portions of the metal substrate 12 are selectively etched by using the mask layers 14 to form recesses 16.

Referring to FIG. 4, the mask layers 14 are removed. Referring to FIG. 5, the entire upper and lower surfaces of the metal substrate 12 are subjected to anodic oxidation to form a metal oxide layer 18 and a metal layer 12a that is disposed at an inner portion of the metal oxide layer 18. In a case where the metal substrate 12 is constructed with an aluminum substrate, the metal oxide layer 18 is constructed with an aluminum oxide layer.

Referring to FIG. 6, the metal oxide layers 18 formed on the upper and lower surfaces of the metal layer 12a are subjected to lapping or polishing to be planarized, so that the vias 20 of which upper and lower portions are exposed are formed in the metal layer 12a. As a result, a package substrate 100 where the vias 20 are formed at predetermined portions, for example at both side portions of the metal oxide layer 18, is obtained.

FIGS. 7 to 9 are cross-sectional views for explaining a structure of a package substrate and a manufacturing method thereof according to another embodiment of the present invention.

Referring to FIG. 7, a metal substrate 12, for example an aluminum substrate, is prepared. A through-hole 22 is formed to penetrate the metal substrate 12. According to a desired design, a plurality of the through-holes 22 may be formed in various sizes. In FIG. 7, a through-hole 22 having a wide area is formed at the central portion of the metal substrate, and through-holes 22 having a narrow area are formed at both side portions thereof.

Referring to FIG. 8, the entire surfaces of the metal substrate 12 in which the through-hole 22 is formed are subjected to anodic oxidation to form a metal oxide layer 18. As a result, in the metal substrate 12, a metal layer 12a is formed at an inner portion of the metal oxide layer 18. In a case where the metal substrate 12 is constructed with an aluminum substrate, the metal oxide layer 18 is constructed with an aluminum oxide layer.

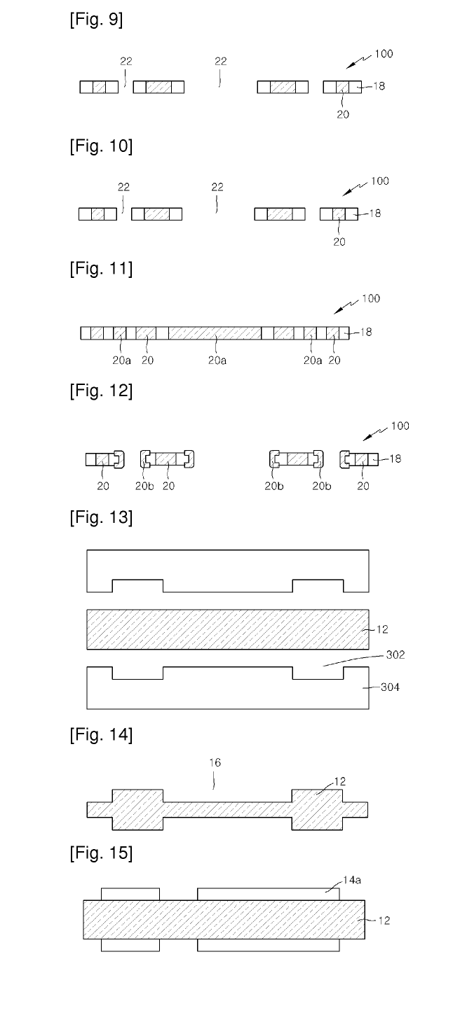

Referring to FIG. 9, the metal oxide layers 18 formed on the upper and lower surfaces of the metal layer 12a are subjected to lapping or polishing to be planarized, so that the vias 20 of which upper and lower portions are exposed are formed in the metal layer 12a. As a result, a package substrate 100 where the vias 20 are formed at both side portions of the metal oxide layer 18 in which the through-hole 22 is formed is obtained.

FIGS. 10 to 12 are cross-sectional views for explaining a structure of a package substrate and a manufacturing method thereof according to still another embodiment of the present invention.

Referring to FIG. 10, the package substrate 100 manufactured in FIG. 9 is prepared. Namely, the package substrate 100 where the vias 20 are formed at both side portions of the metal oxide layer 18 in which the through-hole 22 is formed is obtained.

Referring to FIGS. 11 and 12, a second via 20a and a third via 20b are formed in the through-hole 22 formed in the metal oxide layer 18. The second via 20a is formed so as to fill the through-hole 22 by using a plating process, a silk screen process, or the like. The third via 20b is formed so as to not fill the through-hole 22 completely by forming the metal layer along the surface thereof. As a result, a package substrate 100 where the vias 20, 20a, and 20b in various shapes are formed in the metal oxide layer 18 is obtained. In the specification, the vias are collectively denoted by reference numeral 20.

FIGS. 13 and 14 are cross-sectional views for explaining a structure of a package substrate and a manufacturing method thereof according to further still another embodiment of the present invention.

More specifically, as shown in FIG. 13, a metal substrate 12, for example an aluminum substrate, is prepared. Molds 304 having grooves 302 are disposed on the upper and lower surfaces of the metal substrate 12. As shown in FIG. 14, the metal substrate 12 is pressed by using the molds 304 to form the metal substrate 12 having recesses 16. Since aluminum used for metal substrate 12 is soft and easy to process, mass production of the metal substrates 12 having the recesses 16 can be easily implemented by performing the pressing with the molds.

Subsequently, processes that are the same as those of FIGS. 5 and 6 are performed. Namely, the entire surfaces of the metal substrate 12 having the recesses 16 are subjected to anodic oxidation and the two-side polishing process, so that a package substrate 100 where the vias 20 are formed on both side portions of the metal oxide layer 18 is obtained.

FIGS. 15 to 21 are cross-sectional views for explaining a structure of a package substrate and a manufacturing method thereof according to further still another embodiment of the present invention.

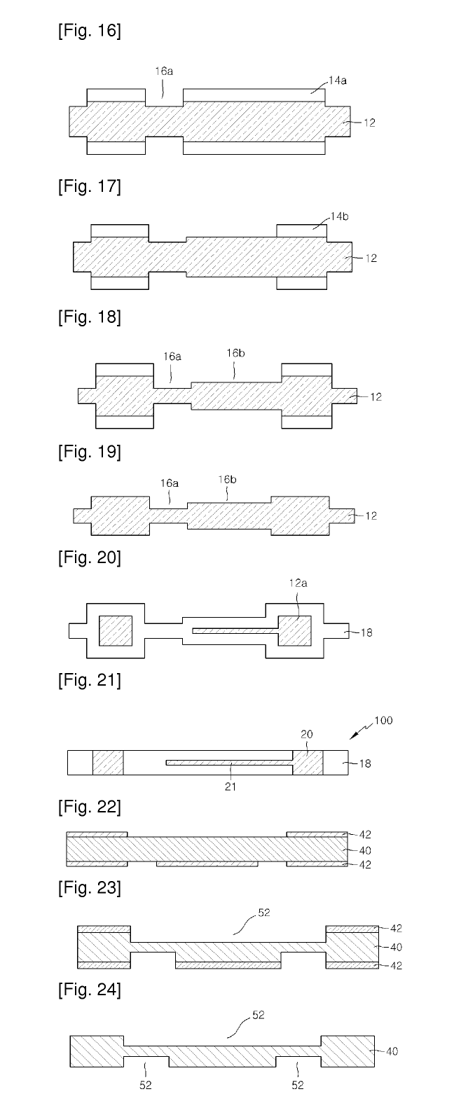

Referring to FIGS. 15 and 16, a metal substrate 12, for example an aluminum substrate, is prepared. First mask layers 14a are formed on the upper and lower surfaces of the metal substrate 12. Some portions of the metal substrate 12 are selectively etched by using the first mask layers 14a to form first recesses 16a.

Referring to FIGS. 17 and 18, the first mask layers 14a are removed. Subsequently, second mask layers 14b are formed on the upper and lower surfaces of the metal substrate 12 in which the first recesses 16a are formed. Some portions of the metal substrate 12 are selectively etched by using the second mask layers 14b to form second recesses 16b. The recesses 16 may be formed by performing the pressing process using the molds similarly to the aforementioned embodiment.

Referring to FIGS. 19 and 20, the second mask layers 14b are removed. The entire surfaces of the metal substrate 12 are subjected to the anodic oxidation to form a metal oxide layer 18. As a result, a metal layer 12a is formed at the inner portion of the metal oxide layer 18. In a case where the metal substrate 12 is constructed with an aluminum substrate, the metal oxide layer 18 is constructed with an aluminum oxide layer.

Referring to FIG. 21, the metal oxide layers 18 formed on the upper and lower surfaces of the metal layer 12a are subjected to lapping or polishing to be planarized, so that the vias 20 of which upper and lower portions are exposed are formed in some portions of the metal layer 12a and a metal plate 21 is formed in the inner portion thereof. As a result, a package substrate 100 where the vias 20 are formed on both side portions of the metal oxide layer 18 and the metal plate 21 is formed in the inner portion thereof is obtained.

In this manner, according to the embodiment, by sequentially adjusting the thickness of the metal substrate, after the anodic oxidation, it is possible to form the metal plate at the inner portion of the metal substrate as well as to form the vias. Accordingly, the metal plate functions as wiring and as a ground plate and a power plate.

FIGS. 22 to 28 are cross-sectional views for explaining a structure of a package substrate and a manufacturing method thereof according to further still another embodiment of the present invention. In FIGS. 22 to 28, a package substrate 100 where a device mounting portion constructed with a metal layer is disposed in the metal oxide layer and the vias 20 are formed in the metal oxide layer is obtained.

Referring to FIG. 22, a base metal substrate 40, for example an aluminum substrate, is prepared. Mask layers 42 are formed on the upper and lower surfaces of the metal substrate 40. The first mask layer 42 formed on the upper surface of the base metal substrate 40 exposes a wide area of the upper surface of the base metal substrate 40, and the first mask layer 42 formed on the lower surface of the base metal substrate 40 exposes a narrow area of the lower surface thereof.

Referring to FIG. 23, some portions of the base metal substrate 40 are selectively etched by using the mask layers 42 to form recesses 52 in the upper and lower surfaces of the base metal substrate 40. The recesses formed on the upper surface of the base metal substrate 40 have a wide width, and the recesses 52 formed on the lower surface of the base metal substrate 40 have a narrow width.

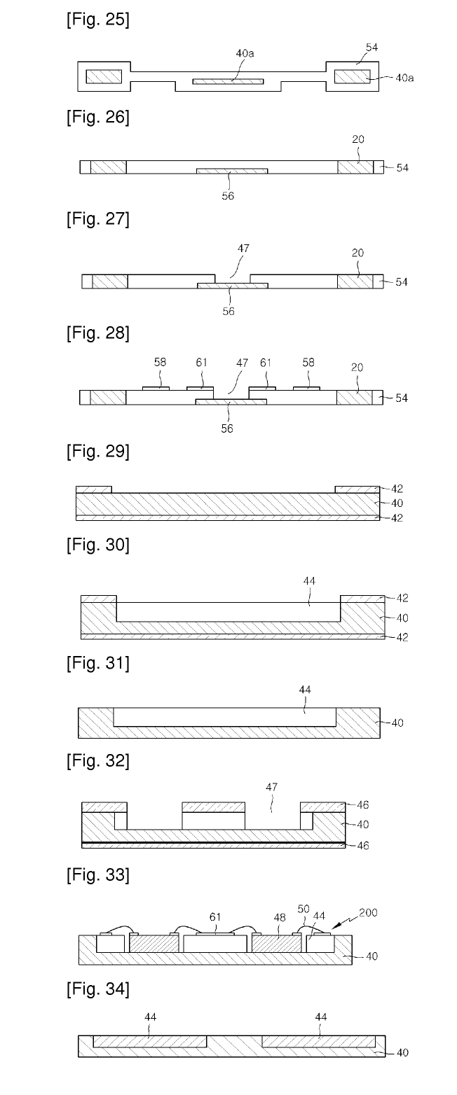

Referring to FIGS. 24 and 25, the mask layers 42 are removed. The entire surfaces of the base metal substrate 40 are subjected to the anodic oxidation to form a metal oxide layer 54. As a result, metal layers 40a are formed on the center portion and both side portions of the metal oxide layer 54. In a case where the base metal substrate 40 is constructed with an aluminum substrate, the metal oxide layer 54 is constructed with an aluminum oxide layer.

Referring to FIG. 26, the metal oxide layer 54 formed on the upper and lower surfaces of the metal layer 40a is subjected to lapping or polishing to be planarized. As a result, the metal layer 40a formed on the central portion of the metal oxide layer 54 is exposed at the lower surface to form the device mounting portion 56, and the metal layers 40a formed on both side portions thereof forms the vias 20 of which upper and lower portions are exposed.

Referring to FIGS. 27 and 28, the metal oxide layer 54 on the device mounting portion 56 is selectively etched to form a cavity 47 in which a device, for example an active device, is to be mounted. Subsequently, passive devices 58 and wiring pads 61 are formed on the metal oxide layer 54 at both sides of the device mounting portion 56. The passive devices 58 may be mounted on a wiring layer (not shown) of the metal oxide layer 54 in a surface mounting manner. Alternatively, the passive devices may be formed by using semiconductor processes.

A base package module and a manufacturing method thereof will now be described.

In the aforementioned schematic view of FIG. 1, one device 48 is mounted on the base metal substrate 40. However, as described below, a plurality of the devices 48 may be mounted on the base metal substrate 40, as needed.

FIGS. 29 to 33 are cross-sectional views for explaining a base package module and a manufacturing method thereof according to an embodiment of the present invention.

Referring to FIG. 29, a base metal substrate 40, for example an aluminum substrate, is prepared. First mask layers 42 are formed on the upper and lower surfaces of the metal substrate 40. The first mask layer 42 formed on the upper surface of the base metal substrate 40 partially exposes the upper surface of the base metal substrate 40, and the first mask layer 42 formed on the lower surface of the base metal substrate 40 is formed on the entire lower surface thereof.

Referring to FIGS. 30 and 31, some portions of the base metal substrate 40 are subjected to selective anodic oxidation by using the first mask layers 42 to form a metal oxide layer 44. Namely, the metal oxide layer 44 is formed on a portion of the base metal substrate 40. Subsequently, the first mask layers 42 are removed.

Referring to FIG. 32, second mask layers 46 that cover some portions of the metal oxide layer 44 and the entire lower surface of the base metal substrate 40 are formed on the base metal substrate 40. Subsequently, the metal oxide layer 44 is etched by using the second mask layer 46 as an etch mask to form a cavity in which the device is to be mounted. According to the present invention, since the cavity 47 is formed by using the etching process, the cavity 47 can be easily processed, and a deviation in size of the cavity can be reduced.

Referring to FIG. 33, the second mask layers 46 are removed. Subsequently, the device 48 is adhered and secured in the cavity 47 by using an adhesive (not shown) such as epoxy. According to the present invention, since the device 48 is mounted in the cavity of the base metal substrate 40, excellent thermal and mechanical characteristics can be obtained in comparison to a convention PCB or LTCC board, so that it is possible to prevent deformation caused from stress. The device 48 is insulated by the metal oxide layer 44 disposed on the side portions in the cavity 47.

Next, by forming wiring pads 61 on the metal oxide layer 44 of the base metal substrate 40 and connecting the electrodes of the device 48 to the wring pads 61, a base package module 200 is obtained.

FIGS. 34 to 39 are cross-sectional views for explaining a base package module and a manufacturing method thereof according to another embodiment of the present invention.

Referring to FIG. 34, a portion of a surface of the base metal substrate 40, for example an aluminum substrate, is subjected to selective anodic oxidation by using a mask process to form a metal oxide layer 44. Namely, the metal oxide layer 44 is formed on some regions of the base metal substrate 40.

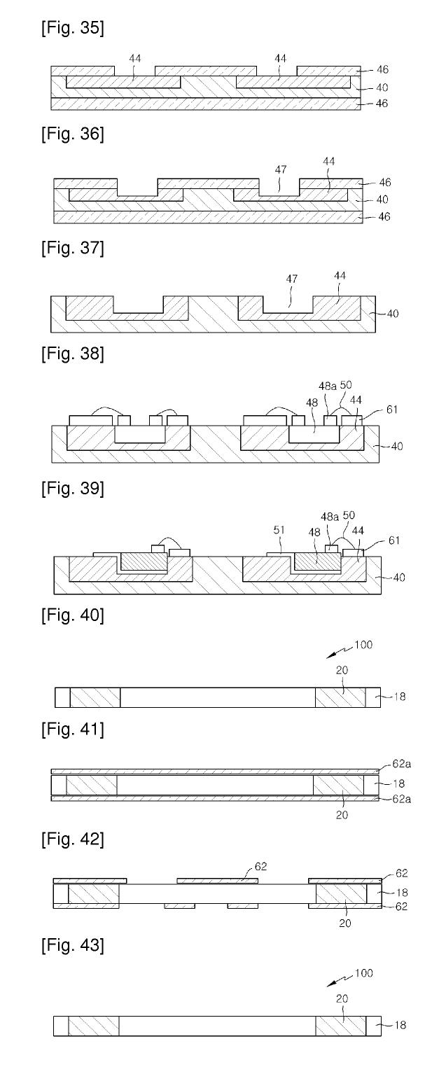

Referring to FIGS. 35 to 37, a mask layer 46 is formed on the base metal substrate 40 to cover a portion of the metal oxide layer 44 and the entire lower surface of the base metal substrate 40. Subsequently, the metal oxide layer 44 is etched by using the mask layer 46 as an etch mask to form a cavity 47 where a device is to be mounted. Next, the mask layer 46 is removed.

Referring to FIGS. 38 to 39, the device 48 is adhered and secured in the cavity 47 by using an adhesive material (not shown) such as epoxy. Consequently, the device 48 is insulated by the metal oxide layer that is formed on a side surface of the cavity 47. Next, the electrode 48a of the device 48 and the wiring pad 61 formed on the metal oxide layer 44 may be connected to each other by using the wire line 50.

Particularly, in FIG. 39, a separate lower electrode 51 is formed on a bottom surface of the cavity, and an upper electrode 48a of the device 48 is connected to the wiring pad 61 by using the wire line 50. As a result, the device 48 having electrodes on the upper and lower portions thereof can be mounted, and the lower electrode 51 can be connected to different signal lines other than the base metal substrate 40.

A connection pad of the package substrate and a forming method thereof will now be described.

FIGS. 40 to 42 are cross-sectional views for explaining a connection pad structure of a package substrate and a formation method thereof according to an embodiment of the present invention.

Referring to FIG. 40, various package substrates 100 are prepared, similar to the aforementioned embodiments. In FIG. 40, for the convenience of description, the package substrate 100 shown in FIG. 6 is exemplified. Namely, in FIG. 40, the package substrate 100 where the vias 20 are formed on both side portions of the metal oxide layer 18 is prepared.

Referring to FIG. 41, metal layers 62a are formed on the upper and lower surfaces of the package substrate including the metal oxide layer 18 and the vias 20. The metal layers 62a may be used to form connection pads, passive devices, and metal wiring layers. The metal layers 62a are formed by attaching metal sheets on the upper and lower surfaces of the package substrate or by using a plating process.

Referring to FIG. 42, the metal layers 62a are wet-etched or dry-etched by using a masking process and an etching process to form connection pads 62, metal wiring, or passive devices. The connection pads 62 are formed on the surface of the metal oxide layer 18 or the surface of the via 20. The connection pads 62 may be used to connect a plurality of the package substrates 100. Alternatively, the connection pads 62, the metal wiring, or the passive devices may be formed by using a silk screen process or the like.

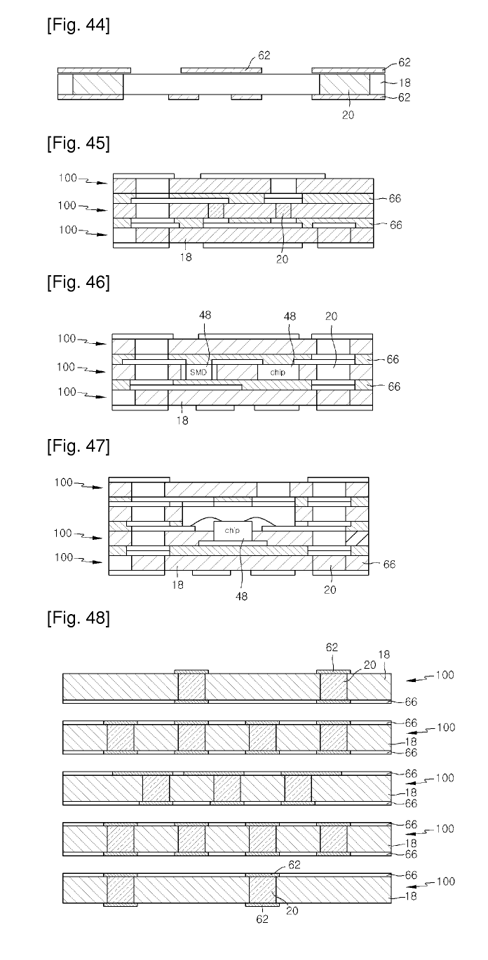

FIGS. 43 and 44 are cross-sectional views for explaining a connection pad structure of a package substrate and a formation method thereof according to another embodiment of the present invention.

Referring to FIG. 43, various package substrates 100 are prepared, similar to the aforementioned embodiments. FIG. 43, for the convenience of description, the package substrate 100 shown in FIG. 6 is exemplified. Namely, in FIG. 43, the package substrate 100 where the vias 20 are formed on both side portions of the metal oxide layer 18 is prepared.

Referring to FIG. 44, the connection pads 62, the metal wiring, or the passive devices are directly formed on the upper and lower surfaces of the package substrate 100 including the metal oxide layer 18 and the vias 20. The connection pads 62, the metal wiring, or the passive devices are formed by using a silk screen process, a semi-conductor process, or the like. The connection pads 62 are formed on the surface of the metal oxide layer 18 or the surface of the via 20. The connection pads 62 may be used to connect a plurality of the package substrates 100.

A multi-layered laminating method for the package substrate including the connection pad and a structure thereof will now be described.

Hereinafter, a multi-layer laminating method for a package substrate provided with connection pads is described. The same multi-layer laminating method may be used to laminate a base package module. A multi-layer laminating method using a package substrate will be described.

FIGS. 45 to 47 are cross-sectional views for explaining a multi-layer laminating method for package substrates and a multi-layer lamination structure according to an embodiment of the present invention.

More specifically, a plurality of the aforementioned package substrates 100 where the connection pads 62 are formed are prepared. In each of the package substrates 100, the vias 20 are formed in the metal oxide layer 18, and the connection pads 62 are formed on the upper and lower portions of the vias 20. According to a desired design of each of the package substrates 100, the connection pads 62 or the vias 20 may be formed in different shapes.

The package substrates 100 where the connection pads 62 are formed are laminated by using adhesive layers 66. Therefore, the adhesive layers 66 are disposed between the package substrates 100. During the lamination of the package substrates 100, the package substrates 100 are connected to each other through the connection pads 62.

In FIGS. 45 to 47, the same elements as those of the aforementioned embodiments are denoted by the same reference numerals.

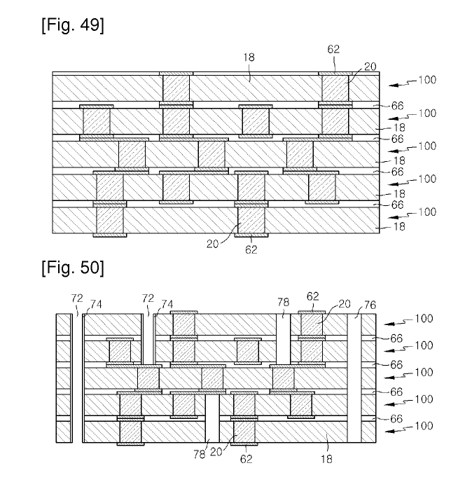

FIGS. 48 and 49 are cross-sectional views for explaining a multi-layer laminating method for package substrates and a multi-layer lamination structure according to another embodiment of the present invention.

Referring to FIG. 48, a plurality of the aforementioned package substrates 100 where the connection pads 62 are formed are prepared. In each of the package substrates 100, the vias 20 are formed in the metal oxide layer 18, and the connection pads 62 are formed on the upper and lower portions of the vias 20. According to a desired design of each of the package substrates 100, the connection pads 62 or the vias 20 may be formed in different shapes. Subsequently, adhesive layers 66 are selectively formed on the upper and lower surfaces of the package substrates 100 by using a silk screen process or the like.

Referring to FIG. 49, the package substrates 100 where the connection pads 62 are formed are laminated and adhered to each other. Therefore, the adhesive layers 66 are disposed between the package substrates 100. During the lamination of the package substrates 100, the package substrates 100 are connected to each other through the connection pads 62.

FIG. 50 is a cross-sectional view for explaining a multi-layer laminating method for package substrates and a multi-layer lamination structure according to still another embodiment of the present invention.

Referring to FIG. 50, multi-layered package substrates 100 are prepared, similar to the aforementioned embodiment. In addition, through-holes 70 that penetrate all the multi-layered package substrates 100 or non-penetrating holes 72 that penetrate some of the multi-layered package substrates 100 are formed. In addition, the through-holes 70 are filled with a metal material to form vias 76. The non-penetrating holes 72 are also filled with a metal material to form vias 78. In FIG. 50, reference numeral 74 denotes a contact metal layer. As shown in FIG. 50, after the package substrates are laminated, the multi-layered package substrates are processed in various shapes so as to be used as a multi-layered package module.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A package substrate, comprising:
a plate-shaped metal oxide layer; and
at least one metal via that is formed to penetrate at least one portion of the metal oxide layer and to have a thickness equal to that of the metal oxide layer, wherein the metal oxide layer is formed by performing oxidation on the entire surface of a metal substrate without a mask, and the metal via corresponds to a portion that is not oxidized during the oxidation of the metal substrate for forming the metal oxide layer.

2. The package substrate of claim 1, wherein the metal is aluminum, and the metal oxide layer is alumina.

3. The package substrate of claim 1, further comprising a metal plate that is disposed in the metal oxide layer.

4. The package substrate of claim 1, further comprising one or more through-holes that penetrate predetermined portions of the metal oxide layer.

5. The package substrate of claim 4, further comprising vias that are formed along inner walls of the through-holes to extend on a portion of the metal oxide layer.

6. The package substrate of claim 1, further comprising a device mounting portion that is constructed by forming a metal layer on a lower surface of the metal oxide layer and forming a cavity on an upper surface of the metal layer.

7. The package substrate of claim 6, wherein a device mounted on the device mounting portion and the package substrate are connected to each other through a conductor line.

8. A multi-layered package module having layered package substrates, wherein the package substrates are laminated by contacting connection pads that are disposed on upper and lower portions of vias.

9. A base package module, comprising:
a base metal substrate;
a first metal oxide layer that is formed on the base metal substrate to have a cavity therein;
a device that is mounted in the cavity on the base metal substrate and insulated by the first metal oxide layer formed on a sidewall in the cavity; and
a conductor that is connected to the device and a wiring pad formed on the first metal oxide layer on the base metal substrate.

10. The base package module of claim 9, further comprising a via that connects upper and lower portions.

11. A multi-layered package module having a base package module and package substrates laminated on upper and lower portions of the base package module, wherein each of the package substrates comprises:
a wiring pad;
a conductor line;
a second metal oxide layer having an opening that exposes a device; and
a via that is connected to the wiring pad through a connection pad in the second metal oxide layer.

12. The multi-layered package module of claim 11, wherein upper portions of the wiring pad, the conductor line, and the device in the opening of the package substrate are filled with an insulating layer.

13. The base package module of claim 9, wherein the first metal oxide layer is formed on a bottom portion of the cavity where the device is mounted.

14. The base package module of claim 13, wherein an electrode is formed on the bottom portion of the cavity on the first metal oxide layer.

15. The multi-layered package module of claim 8, wherein the base package module and the package substrates are adhered to each other with an adhesive layer.

16. The multi-layered package module of claim 8, wherein a penetrating through-hole or a non-penetrating hole is formed.

17. The multi-layered package module of claim 8, wherein a passive device is formed on the metal oxide layer of the package substrate.

18. The multi-layered package module of claim 8, wherein surface mounting type of parts are mounted on the metal oxide layer of the uppermost package substrate or base package module.

19. The multi-layered package module of claim 8, wherein an active device or a passive device is disposed in an inner portion of the package substrate.

20. A method of manufacturing a multi-layered package module, wherein the forming of the cavity and the metal oxide layer comprises:
forming the metal oxide layer by performing selective anodic oxidation on the base metal substrate; and
forming the cavity by selectively etching the metal oxide layer to expose the base metal substrate.

21. The method of claim 20, wherein, in the selectively etching of the metal oxide layer, a portion of the metal oxide layer is left on the base metal substrate.

22. A method of manufacturing a package substrate, comprising:
forming recesses by removing predetermined portions of upper and lower surfaces of a metal substrate;
leaving a predetermined thickness of a metal constituting the metal substrate in portions where the recesses are not formed by oxidizing the entire surface of the metal substrate without a mask until portions of the metal substrate corresponding to the recesses are completely oxidized; and
forming vias by polishing both surfaces of the resulting product until metal surfaces left in the portions where the recesses are not formed are exposed.

23. The method of claim 22, wherein the recesses are formed by etching and removing the predetermined portions.

24. The method of claim 22, wherein the recesses are formed by pressing with a pressing apparatus.

25. The method of claim 22, wherein the forming of the recesses comprises:
forming recesses having non-uniform depths on the upper surface of the metal substrate; and
forming recesses having non-uniform depths on the lower surface of the metal substrate.

26. The method of claim 25, further comprising:
forming the recesses of the metal substrate in an asymmetrical structure;
remaining a predetermined thickness of a metal constituting the metal substrate in portions where the recesses are not formed by oxidizing the metal substrate to form the metal oxide layer; and
forming a device mounting portion having a metal layer on a lower surface thereof by polishing a lower surface of the resulting product until metal surfaces left in the portions where the recesses are not formed are exposed and by etching an upper surface of the metal oxide layer.
